(19) United States
(12) Patent Application Publication
(10) Pub. No.: US 2013/0295714 A1
(43) Pub. Date: Nov. 7, 2013

(54) SYSTEMS AND METHODS FOR SITE CONTROLLED CRYSTALLIZATION

(71) Applicants: Hameed Naseem, Fayetteville, AR (US); Benjamin Newton, Fayetteville, AR (US); Matthew G. Young, Fayetteville, AR (US)

(72) Inventors: Hameed Naseem, Fayetteville, AR (US); Benjamin Newton, Fayetteville, AR (US); Matthew G. Young, Fayetteville, AR (US)

(73) Assignee: BOARD OF TRUSTEES OF THE UNIVERSITY OF ARKANSAS, Little Rock, AR (US)

(21) Appl. No.: 13/875,233

(22) Filed: May 1, 2013

Related U.S. Application Data
(60) Provisional application No. 61/641,596, filed on May 2, 2012.

(51) Int. Cl. H01L 31/20

(52) U.S. Cl. CPC H01L 31/20
USPC 438/96; 118/720; 118/721; 204/298.02

(57) ABSTRACT

Systems and methods for site controlled crystallization are disclosed. According to one aspect, a method for forming a composite film is disclosed. In one example embodiment, the method includes forming a layer of amorphous material. The method also includes forming a layer of metal material on each of a plurality of selected regions of the layer of amorphous material to form a structure including the layer of metal material on the layer of amorphous material, and annealing the structure to generate metal-induced crystallization at the interface of the layer of metal material and each of the selected regions of the layer of amorphous material such that crystalline structures are formed.

### CROSS-REFERENCE TO RELATED APPLICATIONS

This Application claims priority to and benefit under 35 U.S.C §119(e) of U.S. Provisional Patent Application Ser. No. 61/641,596, entitled “Site Controlled Crystallization,” filed May 2, 2012, which is hereby incorporated by reference herein in its entirety.

### STATEMENT OF FEDERALLY SPONSORED RESEARCH

Research related to one or more aspects of the disclosure provided herein has been funded through the University of Arkansas Distinguished Doctoral Fellowship and through the SMART scholarship which is funded by the (OSD-T&E) Office of Secretary of Defense—Test and Evaluation Defense-Wide/PE0601120D8Z National Defense Education Program (NDEP)/Ba-1 Basic Research (Grant Number N00244-09-1-0081) and NSF/ASTA funding. The United States government may have certain rights in one or more aspects of the disclosure pursuant to this funding.

### TECHNICAL FIELD

The present disclosure relates generally to composite films and, more particularly, to composite thin films and solar cells formed by site controlled crystallization.

### BACKGROUND

Silicon is the second most abundant element in the earth's crust. It has been the dominant material of choice for the semiconductor and solar cell industries. Silicon solar cells throughout the solar cell industry can be found with three different forms of silicon, namely monocrystalline silicon, amorphous silicon, and polycrystalline silicon.

The materials most commonly used for thin film silicon solar cells are amorphous silicon and polycrystalline materials. The polycrystalline materials most used are polycrystalline silicon, cadmium telluride or cadmium indium (gallium) deselenide. All of these are amenable to large area deposition, with amorphous silicon being the more developed of the thin film processes. Monocrystalline silicon has a highly periodic structure which aids in charge carrier mobility. As an indirect bandgap semiconductor, a vast majority of the recombination that occurs within monocrystalline silicon will be due to impurities or lattice defects. Having a highly periodic structure throughout the material, in contrast to polycrystalline silicon or amorphous silicon, allows moncrystalline silicon to have an advantage in charge carrier transport over these other two forms of silicon.

However, monocrystalline silicon can have relatively poor absorption properties. Direct band gap semiconductors, when exposed to photons, need energy equivalent to the bandgap energy to directly transition electrons from the valence band to the conduction band, whereas indirect band gap semiconductors need much larger photon energies to get direct transitions from the valence band to the conduction band. In order for an electron to make the full transition to the valence band in indirect bandgap semiconductors, it needs a photon and a phonon.

The probability of the indirect bandgap semiconductor obtaining a photon of the right energy and a phonon can be lower than the probability of a direct bandgap semiconductor obtaining only a photon. This causes a lowering of the absorption coefficient, as the light must travel further into the monocrystalline material before it is absorbed. This requires more indirect bandgap material for comparable absorption in direct bandgap material.

Amorphous silicon is an allotropic form of silicon. It is a direct bandgap semiconductor and its absorption properties are much greater than those of monocrystalline silicon. Amorphous silicon can also have drawbacks. Being an amorphous material means that it has no long or short term periodic structure. There will be more defects and dangling unterminated atoms present in this state of silicon. The high level of defects and dangling bonds causes there to be a greater probability that charge carriers will be trapped at these sites and never collected.

Polycrystalline silicon is a form of silicon that is a collection of monocrystalline crystallites connected through grain boundaries. Polycrystalline silicon is an indirect bandgap semiconductor with the same bandgap as monocrystalline silicon, but its carrier transport properties suffer because of the grain boundaries surrounding the numerous crystallites. These grain boundaries are composed of disordered atoms of silicon and serve as recombination sites for photogenerated carriers. Inside these grain boundaries, the crystalline silicon may have different crystal orientation than its neighbors.

It is with respect to these and other considerations that the disclosure made herein is presented.

### SUMMARY

It should be appreciated that this Summary is provided to introduce a selection of concepts in a simplified form that are further described below in the Detailed Description. This Summary is not intended to be used to limit the scope of the claimed subject matter.

According to one aspect, a method is disclosed for forming a composite film. In one example embodiment, the method includes forming a layer of amorphous material, and forming a layer of metal material on each of a plurality of selected regions of the layer of amorphous material, to form a structure including the layer of metal material on the layer of amorphous material. The method also includes annealing the structure to generate metal-induced crystallization at the interface of the layer of metal material and each of the selected regions of the layer of amorphous material such that crystalline structures are formed.

According to another aspect, an apparatus for forming a composite film is disclosed. In one example embodiment, the apparatus includes a system configured to form a layer of amorphous material, and a system configured to form a layer of metal material on each of a plurality of selected regions of the layer of amorphous material, to form a structure including the layer of metal material on the layer of amorphous material. The apparatus also includes a system configured to anneal the structure to generate metal-induced crystallization at the interface of the layer of metal material and each of the selected regions of the layer of amorphous material such that crystalline structures are formed.

According to another aspect, a method for forming a composite solar cell is disclosed. In one example embodiment, the method includes forming a layer of metal material on a substrate, and heating the layer of metal material and substrate to transform the layer of metal material into a plurality of distributed portions of the metal material on the substrate. The method also includes placing the substrate with the plurality of distributed metal portions in an environment selected to crystallize the distributed portions of metal material into a plurality of crystalline nanostructures that include nanowires, and forming a layer of amorphous material to cover and surround the crystalline nanostructures.

According to another aspect, an apparatus for forming a composite solar cell is disclosed. In one example embodiment, the apparatus includes a system configured to form layer of metal material on a substrate, and a system configured to heat the layer of metal material and substrate to transform the layer of metal material into a plurality of distributed portions of the metal material on the substrate. The apparatus also includes a system configured to place the substrate with the plurality of distributed portions of metal material in an environment selected to crystallize the distributed portions of metal material into a plurality of crystalline nanostructures including nanowires, and a system configured to form a layer of amorphous material to cover and surround the crystalline nanostructures.

According to another aspect, a method for forming a composite solar cell is disclosed. In one example embodiment, the method includes forming a layer of amorphous material on a substrate and forming a layer of metal material on the layer of amorphous material. The method also includes heating the layer of metal material and substrate to transform the layer of metal material into a plurality of distributed portions of the metal material on the layer of amorphous material, such that a structure including the distributed portions of metal material, layer of amorphous material, and substrate is formed. The method also includes placing the structure in an environment selected to crystallize the distributed portions of metal material into a plurality of crystalline nanostructures including nanowires that extend into the layer of amorphous material.

According to another aspect, an apparatus for forming a composite solar cell is disclosed. In one example embodiment, the apparatus includes a system configured to form a layer of amorphous material on a substrate, and a system configured to form a layer of metal material on the layer of amorphous material. The apparatus also includes a system configured to heat the layer of metal material at a predetermined temperature to transform the layer of metal material into a plurality of distributed portions of the metal material on the layer of amorphous material, such that a structure comprising the distributed portions of metal material, layer of amorphous material, and substrate is formed. The apparatus also includes a system configured to place the structure in an environment selected to crystallize the distributed portions of metal material into a plurality of crystalline nanostructures including nanowires that extend into the layer of amorphous material.

The features, functions, and advantages discussed herein can be achieved independently in various embodiments of the concepts and technologies disclosed herein, or may be combined in yet other embodiments, further details of which can be seen with reference to the following description and drawings.

### BRIEF DESCRIPTION OF THE DRAWINGS

FIG. 1 is a diagram of a structure including layers of amorphous material and metal material formed on a substrate prior to metal-induced crystallization, according to one example embodiment.

FIG. 2 is a diagram of a structure with a composite thin film formed by controlled metal-induced crystallization, according to one example embodiment.

FIGS. 3A and 3B are diagrams of a composite solar cell formed with crystalline nanostructures, according to one example embodiment.

FIG. 4 is a diagram of a composite solar cell formed with crystalline nanostructures, according to another example embodiment.

FIG. 5 is a diagram of a system for forming composite thin films, according to one example embodiment.

FIG. 6 is a flow diagram illustrating a method for forming a composite film in accordance with one example embodiment.

FIG. 7 is a flow diagram illustrating a method for forming a composite solar cell in accordance with one example embodiment.

### DETAILED DESCRIPTION

The following detailed description is directed to concepts and technologies for forming composite thin films and composite solar cells.

As used herein, “about” or “approximately” shall generally mean within 20 percent, preferably within 10 percent, and more preferably within 5 percent of a given value range. Numerical quantities given herein are approximate, meaning that the term “about” or “approximately” can be inferred if not expressly stated.

It is also to be understood that the mention of one or more steps of a method does not preclude the presence of additional method steps or intervening method steps between those steps expressly identified. Steps of a method may be performed in a different order than those described herein. Similarly, it is also to be understood that the mention of one or more components in an apparatus or system does not preclude the presence of additional components or intervening components between those components expressly identified.

In the following detailed description, references are made to the accompanying drawings that form a part hereof and that show, by way of illustration, specific embodiments or examples. In referring to the drawings, like numerals represent like elements throughout the several figures.

One or more aspects of embodiments disclosed herein relate to controlling the size of metal in contact with the surface of an amorphous semiconductor thin film, such that selected regions on the amorphous semiconductor can be crystallized while leaving the surrounding area in its amorphous state. The amount of crystallinity in an amorphous thin film can thereby be controlled. This can lead to radial junctions within a thin film and band gap engineering opportunities with amorphous semiconductors. A composite material with precise control of the amount of crystalline semiconductor material and amorphous semiconductor material may be used to take advantage of the absorption characteristics of amorphous semiconductor materials and the electron transport characteristics of crystalline semiconductor materials. One or more other aspects of example embodiments disclosed herein relate to nanowires in a matrix of amorphous material in a composite solar cell.

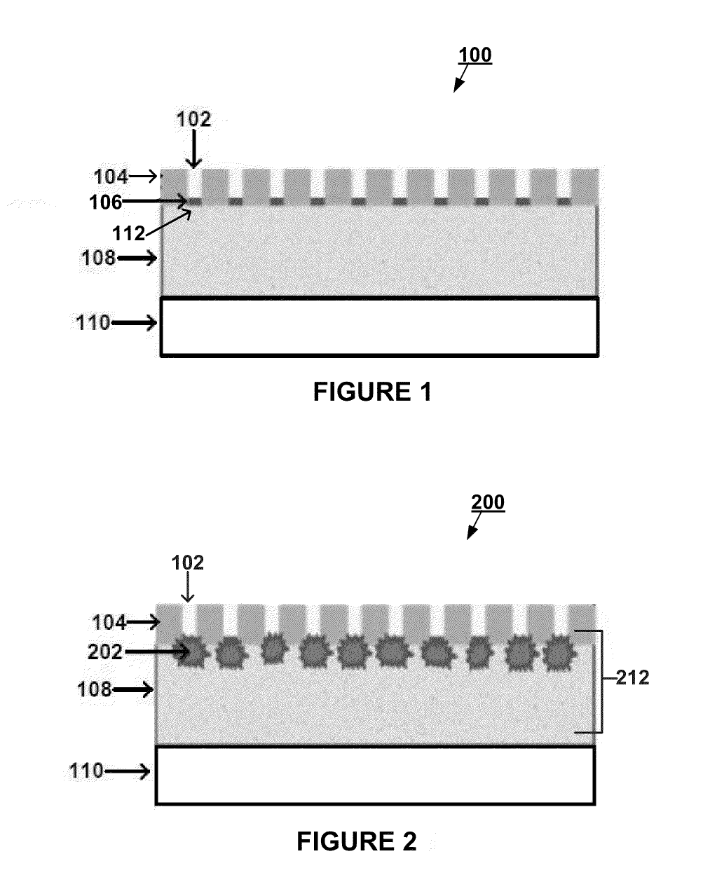

Referring now to FIGS. 1 and 2, a structure having a composite thin film formed by implementing methods and using apparatuses according to example embodiments described herein is disclosed. According to one example embodiment, as shown, a composite thin film 212 is formed by depositing a layer of amorphous material 108 on a substrate 110. Distributed portions of a predetermined amount of metal material 106 are then deposited at selected regions 112 on the top surface of the amorphous layer 108. As used herein, each of the distributed portions may also be referred to as a “dot” or “nanodot.” A structure 100 is thereby formed which has the metal portions 106 formed at each of the selected regions 112. The metal portions can be deposited through apertures 102 in a mask layer 104. The structure 100 is annealed at a predetermined temperature and for a predetermined period of time to generate metal-induced crystallization at an interface of the metal portions 106 and the selected regions 112 on the amorphous layer 108. As shown in the example embodiment of FIG. 2, a structure 200 is thereby formed which has a composite thin film 212 including crystallized material 202 within amorphous material.

The amorphous layer 108 can be comprised of amorphous silicon formed to have a thickness of about 500 nm. The metal portions 106 can be comprised of aluminum formed to have a thickness of about 50 nm, deposited through apertures 102 in the mask layer 104. The mask layer can be comprised of about 50 nm of silicon dioxide. The structure 100 shown in FIG. 1 can be annealed for about 30 minutes at a temperature of about 350° C. in order to produce the structure 200 shown in FIG. 2.

Now also referring to FIG. 5, according to an example embodiment, the amorphous silicon layer 108 can be formed by utilizing chambers 502 or 504 of a plasma enhanced chemical vapor deposition (PECVD) cluster tool 500. The aluminum portions can be formed through the use of a sputtering chamber 506. The structure 100 can be annealed in another chamber 510 at a temperature in a range between about 25° C. and about 400° C. and at a pressure below 10⁻³ torr. The silicon dioxide mask layer 104 can be formed by utilizing a sputtering chamber 508. Prior to forming the aluminum portions 106, apertures 102 in the mask layer 104 can be formed by delivering a focused ion beam to selected portions of the mask layer 104 that correspond to the selected regions 112 on the top surface of the amorphous silicon layer 108.

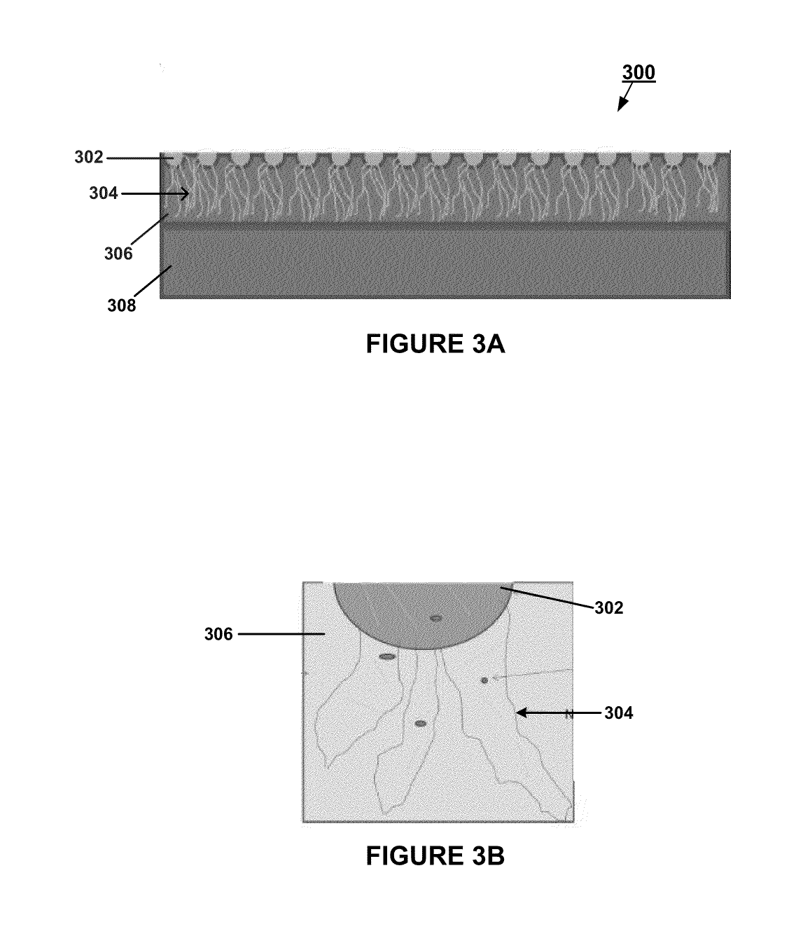

Now referring to FIGS. 3A and 3B, a composite solar cell 300 is formed by implementing methods and through the use of apparatuses described herein according to example embodiments. According to one example embodiment, the composite solar cell 300 is formed by depositing a layer of amorphous material 306 on a top surface of a substrate 308 and forming a layer of metal material on the layer of amorphous material 306. The metal layer is heated to transform the metal layer into a plurality of distributed portions of the metal material. A structure with the distributed metal portions, amorphous layer 306, and substrate 308 is thereby formed. The structure is then placed in an environment that is selected to crystallize the metal portions into a plurality of crystalline nanostructures 302, 304 with nanowires 304 extending into the amorphous layer 306.

In one example embodiment, the metal material includes gold. Alternatively, the metal material can include aluminum. The amorphous material can include amorphous silicon and the selected environment can include silane.

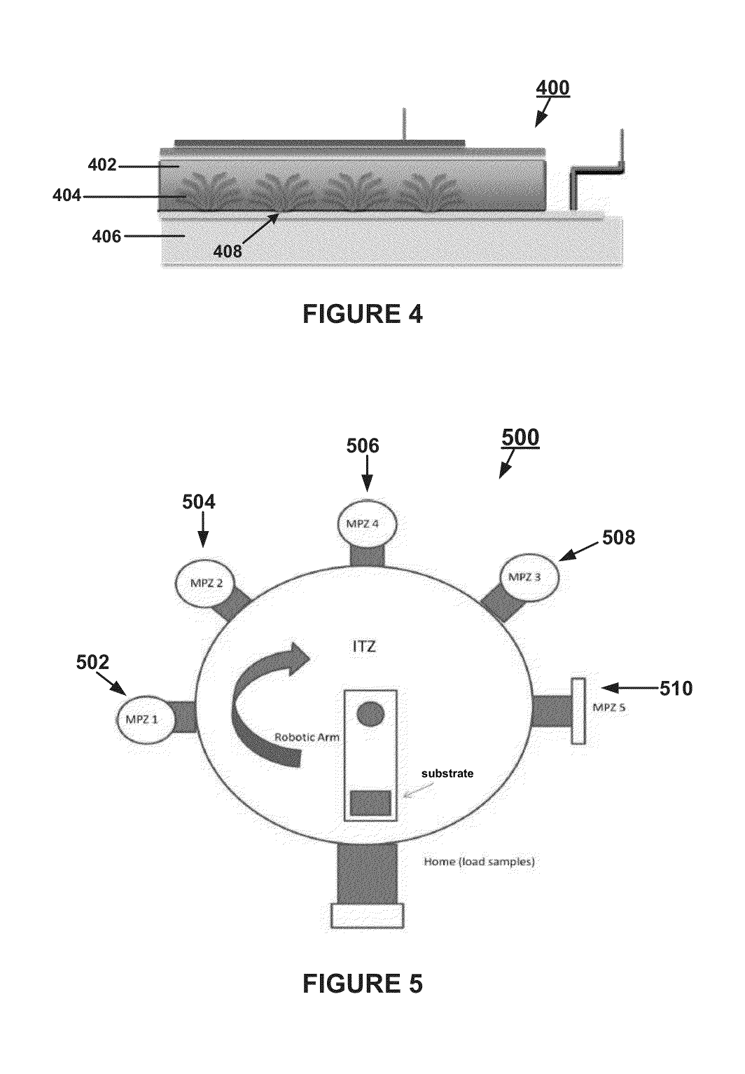

Now referring to FIG. 4, a composite solar cell 400 is formed by implementing methods and using apparatuses according to example embodiments described herein. In one example embodiment, the composite solar cell 400 is formed by depositing a layer of metal material on a substrate 406. The metal layer and substrate 406 are heated at a predetermined temperature and for a predetermined period of time to transform the metal layer into distributed portions of the metal material on regions 408 of the substrate 406. The substrate 406 with the metal portions is placed in an environment selected to crystallize the metal portions into nanostructures 404 that include crystalline nanowires. A layer of amorphous material 402 is formed to cover and surround the crystalline nanostructures 404.

In one example embodiment, the layer of amorphous material 402 can be formed prior to placing the substrate 406 with the distributed metal portions in the selected environment. Alternatively, the layer of amorphous material 402 can be formed after the substrate 406 with the distributed metal portions has been placed in the selected environment. In one example embodiment, the metal includes gold or aluminum and the selected environment includes silane. The amorphous material can include amorphous silicon.

Now referring to FIG. 5, a cluster tool 500 is shown, which can be utilized to implement methods according to example embodiments herein and which can include one or more component systems for apparatuses according to example embodiments disclosed herein. The cluster tool 500, which may be an MVSystems cluster tool, has five deposition chambers 502, 504, 506, 508, and 510, which may also be referred to as MPZ1, MPZ2, MPZ4, MPZ3, and MPZ5, respectively. Chambers 502 and 504 are used for PECVD, where chamber 502 is designated for deposition of undoped hydrogenated amorphous silicon and chamber 504 is designated for deposition of doped hydrogenated silicon. Chamber 508 is designated for sputtering silicon dioxide, and chamber 506 is designated for aluminum sputtering. Chamber 510 can be used for annealing at temperatures ranging from 25° C. to above 400° C. and at pressures of 10⁻³ torr or lower.

In accordance with example embodiments described above with respect to FIGS. 1 and 2, deposition of 500 nm of amorphous silicon onto a substrate can be performed in chamber 502. The flow rate of silane can be 20 sccm with a chamber pressure of 5 mtorr and a substrate temperature of 250° C. Chamber 508 can be used for sputter deposition of 50 nm of silicon dioxide at 250° C. and with an argon flow rate of 20 sccm and an oxygen flow rate of 4 sccm.

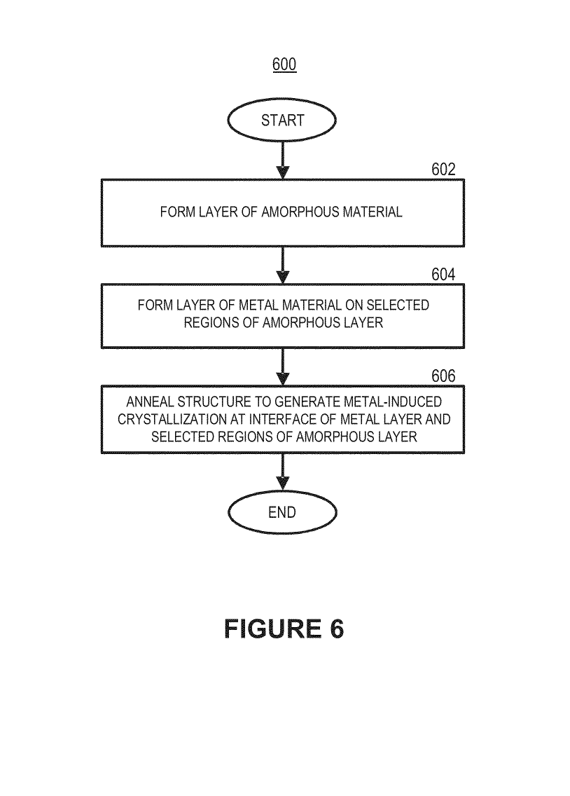

FIG. 6 is a flow diagram illustrating a method 600 for forming a composite film, in accordance with one example embodiment. The method 600 begins at block 602, where a layer of amorphous material is formed. At block 604, a layer of metal material is formed on each of a plurality of selected regions of the layer of amorphous material to form a structure including the layer of metal material on the layer of amorphous material. At block 606, the structure is annealed to generate metal-induced crystallization at the interface of the layer of metal material and each of the selected regions of the layer of amorphous material such that crystalline structures are formed. The method 600 ends following block 606.

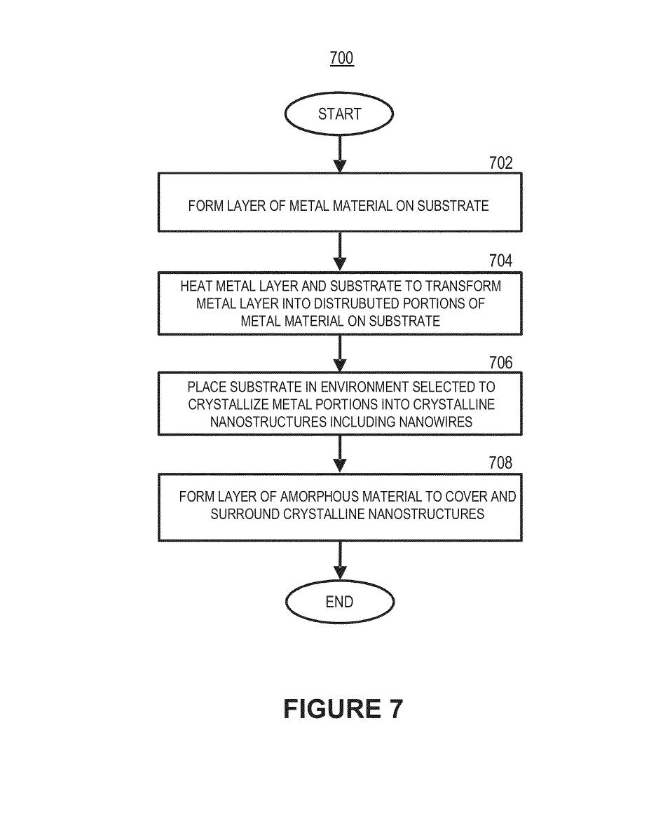

FIG. 7 is a flow diagram illustrating a method 700 for forming a composite solar cell, in accordance with one example embodiment. The method 700 begins at block 702, where a layer of metal material is formed on a substrate. At block 704, the layer of metal material and substrate are heated to transform the layer of metal material into a plurality of distributed portions of the metal material on the substrate. At block 706, the substrate with the plurality of distributed metal portions is placed in an environment selected to crystallize the distributed portions of metal material into a plurality of crystalline nanostructures including nanowires. The nanowires can extend into the layer of amorphous material. At block 708, a layer of amorphous material is formed to cover and surround the crystalline nanostructures. The method 700 ends following block 708.

Based on the foregoing, it should be appreciated that concepts and technologies for forming composite thin films and solar cells by site controlled crystallization are provided herein. Although the subject matter presented herein has been described in language specific to structural features and methodological acts, it is to be understood that the invention defined in the appended claims is not necessarily limited to the specific features or acts described herein. Rather, the specific features and acts are disclosed as example forms of implementing the claims.

The subject matter described above is provided by way of illustration only and should not be construed as limiting. Various modifications and changes may be made to the subject matter described herein without following the example embodiments and applications illustrated and described, and without departing from the true spirit and scope of the present invention, which is set forth in the following claims.

What is claimed is:

1. A method for forming a composite film, comprising:
forming a layer of amorphous material;
forming a layer of metal material on each of a plurality of selected regions of the layer of amorphous material to form a structure comprising the layer of metal material on the layer of amorphous material; and
annealing the structure to generate metal-induced crystallization at the interface of the layer of metal material and each of the selected regions of the layer of amorphous material such that crystalline structures are formed.

2. The method of claim 1, wherein each of the crystalline structures, as formed, is surrounded by at least one portion of the amorphous material.

3. The method of claim 1, wherein forming the layer of metal material on each of the plurality of selected regions of the layer of amorphous material comprises forming a metal dot, comprised of a predetermined amount of the metal material, on each of the selected regions of the layer of amorphous material.

4. The method of claim 1, wherein annealing the structure to generate metal-induced crystallization at the interface of the layer of metal material and each of the selected regions of the layer of amorphous material comprises annealing the structure to generate metal-induced crystallization at the interface of a metal dot, comprised of a predetermined amount of the metal material, and each of the selected regions of the layer of amorphous material.

5. The method of claim 1, wherein the structure is annealed for a predetermined period of time and at a predetermined temperature selected to generate the metal-induced crystallization.

6. The method of claim 5, wherein the predetermined period of time is about 30 minutes and the predetermined temperature is about 350° C.

7. The method of claim 1, wherein the layer of metal material is formed on each of the selected regions of layer of the amorphous material through a plurality of corresponding apertures in a mask layer to the layer of amorphous material.

8. The method of claim 7, wherein forming the layer of metal material on each of the selected regions of the layer of amorphous material comprises delivering a focused ion beam to form an aperture through a portion of the mask layer to the layer of amorphous material.

9. The method of claim 1, wherein the layer of amorphous material, as formed, has a thickness of about 500 nanometers.

10. The method of claim 1, wherein the layer of metal material, as formed, has a thickness of about 50 nanometers.

11. An apparatus for forming a composite film, comprising:
a system configured to form a layer of amorphous material;
a system configured to form a layer of metal material on each of a plurality of selected regions of the layer of amorphous material to form a structure comprising the layer of metal material on the layer of amorphous material; and
a system configured to anneal the structure to generate metal-induced crystallization at the interface of the layer of metal material and each of the selected regions of the layer of amorphous material such that crystalline structures are formed.

12. The apparatus of claim 11, wherein each of the crystalline structures, as formed, is surrounded by at least one portion of the amorphous material.

13. The apparatus of claim 11, wherein the system configured to form the layer of metal material on each of the plurality of selected regions of the layer of amorphous material is configured to form a metal dot, comprised of a predetermined amount of the metal material, on each of the selected regions of the layer of amorphous material.

14. The apparatus of claim 11, wherein the system configured to anneal the structure to generate metal-induced crystallization at the interface of the layer of metal material and each of the selected regions of the layer of amorphous material is configured to anneal the structure to generate metal-induced crystallization at the interface of a metal dot, comprised of a predetermined amount of the metal material, and each of the selected regions of the layer of amorphous material.

15. The apparatus of claim 11, wherein the system configured to anneal the structure to generate metal-induced crystallization at the interface of the layer of metal material and each of the selected regions of the layer of amorphous material is configured to anneal the structure for a predetermined period of time and at a predetermined temperature selected to generate the metal-induced crystallization.

16. The apparatus of claim 15, wherein the predetermined period of time is about 30 minutes and the predetermined temperature is about 350° C.

17. The apparatus of claim 11, wherein the system configured to form a layer of metal material on each of a plurality of selected regions of the layer of amorphous material is configured to form the layer of metal material on each of the selected regions of the layer of the amorphous material through a plurality of corresponding apertures in a mask layer to the layer of amorphous material.

18. The apparatus of claim 17, wherein the system configured to form a layer of metal material on each of a plurality of selected regions of the layer of amorphous material comprises a system configured to deliver a focused ion beam to form an aperture through a portion of the mask layer to the layer of amorphous material.

19. The apparatus of claim 11, wherein the layer of amorphous material, as formed, has a thickness of about 500 nanometers.

20. The apparatus of claim 11, wherein the layer of metal material, as formed, has a thickness of about 50 nanometers.

21. The apparatus of claim 11, wherein the system configured to form the layer of amorphous material comprises a plasma-enhanced chemical vapor deposition (PECVD) system.

22. The apparatus of claim 11, wherein the system configured to form the layer of metal material comprises a sputtering system.

23. The apparatus of claim 11, wherein the system configured to form the layer of metal material comprises a molecular beam epitaxy means.

24. A method for forming a composite solar cell, comprising:
forming a layer of metal material on a substrate;
heating the layer of metal material and substrate to transform the layer of metal material into a plurality of distributed portions of the metal material on the substrate;
placing the substrate with the plurality of distributed metal portions in an environment selected to crystallize the distributed portions of metal material into a plurality of crystalline nanostructures comprising nanowires; and
forming a layer of amorphous material to cover and surround the crystalline nanostructures.

25. The method of claim 24, wherein forming the layer of amorphous material is performed prior to placing the substrate with the distributed portions of metal material in the selected environment.

26. The method of claim 24, wherein forming the layer of amorphous material is performed after the substrate with the distributed portions of metal material has been placed in the selected environment.

27. A method for forming a composite solar cell, comprising:
forming a layer of amorphous material on a substrate;
forming a layer of metal material on the layer of amorphous material;
heating the layer of metal material and substrate to transform the layer of metal material into a plurality of distributed portions of the metal material on the layer of amorphous material, such that a structure comprising the distributed portions of metal material, layer of amorphous material, and substrate is formed; and
placing the structure in an environment selected to crystallize the distributed portions of metal material into a plurality of crystalline nanostructures comprising nanowires extending into the layer of amorphous material.

28. An apparatus for forming a composite solar cell, comprising:
a system configured to form layer of metal material on a substrate;
a system configured to heat the layer of metal material and substrate to transform the layer of metal material into a plurality of distributed portions of the metal material on the substrate;
a system configured to place the substrate with the plurality of distributed portions of metal material in an environment selected to crystallize the distributed portions of metal material into a plurality of crystalline nanostructures comprising nanowires; and
a system configured to form a layer of amorphous material to cover and surround the crystalline nanostructures.

29. The apparatus of claim 28, wherein the system configured to form the layer of amorphous material is configured to form the layer of amorphous material prior to placing the substrate with the distributed portions of metal material in the selected environment.

30. The apparatus of claim 28, wherein the system configured to form the layer of amorphous material is configured to form the layer of amorphous material after the substrate with the distributed portions of metal material has been placed in the selected environment.

31. A method for forming a composite solar cell, comprising:
forming a layer of amorphous material on a substrate;
forming a layer of metal material on the layer of amorphous material;
heating the layer of metal material and substrate to transform the layer of metal material into a plurality of distributed portions of the metal material on the layer of amorphous material, such that a structure comprising the distributed portions of metal material, layer of amorphous material, and substrate is formed; and
placing the structure in an environment selected to crystallize the distributed portions of metal material into a plurality of crystalline nanostructures comprising nanowires extending into the layer of amorphous material.

32. An apparatus for forming a composite solar cell, comprising:
a system configured to form a layer of amorphous material on a substrate;
a system configured to form a layer of metal material on the layer of amorphous material;
a system configured to heat the layer of metal material at a predetermined temperature to transform the layer of metal material into a plurality of distributed portions of the metal material on the layer of amorphous material, such that a structure comprising the distributed portions of metal material, layer of amorphous material, and substrate is formed; and
a system configured to place the structure in an environment selected to crystallize the distributed portions of metal material into a plurality of crystalline nanostructures comprising nanowires extending into the layer of amorphous material.
